(19) United States
(12) Patent Application Publication
(10) Pub. No.: US 2002/0168837 A1
(43) Pub. Date: Nov. 14, 2002

(54) Method of fabricating silicon devices on sapphire with wafer bonding

(75) Inventors: Louis L. Hsu, Fishkill, NY (US); Leathen Shi, (US); Li-Kong Wang, Montvale, NJ (US)

Correspondence Address: Louis J. Percello, Intellectual Property Law Dept., IBM Corporation, P.O. Box 218, Yorktown Heights, NY, 10598, US

(73) Assignee: IBM

(21) Appl. No.: 09/852,329

(22) Filed: May 9, 2001

(51) Int. Cl. H01L 21/425

(52) U.S. Cl. 438/517

(57) ABSTRACT

A improved method of making of silicon on sapphire structure and/or device is disclosed. In a first preferred embodiment, a single silicon oxide layer is placed between the silicon layer and the sapphire layer. This can be done by attaching the silicon oxide layer on the silicon layer, e.g. by growing or depositing, and then attaching the sapphire layer to the oxide layer using wafer bonding. In an alternative embodiment, a first silicon oxide layer is attached to the silicon layer, e.g. by growing or depositing. A second silicon oxide layer is then attached to the sapphire layer, e.g. by depositing. Then the first and second silicon oxide layers are attached by a wafer bonding technique.

### FIELD OF THE INVENTION

This invention relates to the field of manufacturing a semiconductor substrate. More specifically, the invention relates to the field of manufacturing micro-wave and radio frequency integrated circuits on a silicon on sapphire substrate.

### BACKGROUND OF THE INVENTION

CMOS devices built on the silicon on insulator (SOI) substrates can have enhanced performance due to reduction of parasitic capacitance, increasing carrier mobility. This kind of high performance device and circuit technology at present can be applied to operate at GHz RF applications. Integration of RF passive components with this kind of technology enables high performance, high integration level, low cost RF integrated circuits. However most of the chips today are built on silicon based substrate including the SOI wafers including the SOI wafers. This becomes a major drawback in RF applications because the conducting silicon substrate becomes a lose path in the substrate when the circuit and passive components are switching at RF frequency. A typical example is the inductor induced Eddy current in the substrate from the current flowing in the coil. The reduction of the Q factor due to the energy loss in the substrate can significantly downgrade the efficiency of the circuits. Building devices and components on an insulating substrate can not only reduce dissipation loss and but also the insulator substrate is transparent to the RF wave signals. Sapphire is a highly transparent material at RF frequency with an excellent insulating property. It also is an excellent thermally conductive material which avoids local or global hot spots. To build silicon devices on sapphire substrate has been successfully demonstrated for many years.

The most common method to form silicon on sapphire has been reported in U.S. Pat. No. 4,509,990, entitled “Solid Phase Epitaxy and Regrowth Process with Controlled Defect Density Profiling for Hetroepitaxial Semiconductor on Insulator Composite Substrates”. The silicon on sapphire substrate is formed by depositing an amorphous silicon material on a sapphire substarte followed by an expitaxial regrowth under laser annealing. However, none of these prior art methods can produce good quality silicon film on top of the sapphie substrate.

Although silicon on sapphire devices have been investigated for almost 30 years due to the attractive device advantages, still no reliable method exists to make high quality substrates to satisfy the device fabrication need, particularly in high frequency applications.

High defect density caused by lattice mismatch between silicon layer and the underneath sapphire substrate greatly degrades the device performance. Defects such as dislocations, twins, and micro-cracks are found at the interface between the epitaxy silicon layer and sapphire substrate which results in high leakage currents.

Using melting and re-crystallization approach mentioned in the prior art to create silicon islands on sapphire substrates is known to cause high defect density in the silicon device layer and therefore can not be used to build high-performance RF and microwave integrated circuits.

### OBJECT OF THE INVENTION

An object of this invention is an improved method of making a silicon on sapphire substrate.

An object of this invention is an improved method of making a silicon on sapphire substrate by using a wafer bonding technique.

An object of this invention is an improved method of making a silicon on sapphire substrate by wafer bonding using an oxide layer as the bonding material.

An object of this invention is an improved method of making a silicon on sapphire substrate by wafer bonding with two separate and adjacent oxide layers as the bonding material, one on the silicon layer and one on the sapphire substrate.

An object of this invention is an improved method of making a silicon on sapphire substrate by wafer bonding with a prefabricated bonding structures on both silicon and sapphire wafers, where these prefabricated bonding structures are used to improved the material characteristics of silicon on sapphire.

Another object of this invention is to take advantage of optically transparent property of the sapphire to achieve precision alignment during wafer bonding to align the prefabricated structures.

### SUMMARY OF THE INVENTION

The present invention is an improved method of making of silicon on a sapphire structure. In a first preferred embodiment, a silicon oxide layer is placed between the silicon layer and the sapphire layer. This can be done by forming the silicon oxide layer on the silicon layer, e.g. by growing or CVD depositing, and then attaching the sapphire substrate to the oxide layer that formed on the silicon substrate using a wafer bonding technique. In an alternative embodiment, a first silicon oxide layer is formed to the silicon layer, e.g. by growing or CVD depositing. A second silicon oxide layer is then formed to the sapphire layer, e.g. by CVD depositing. Then the first silicon oxide layer on the silicon wafer and second silicon oxide layers on the sapphire wafer are joined by a wafer bonding technique.

### BRIEF DESCRIPTION OF THE FIGURES

FIG. 1 is a perspective view of the first preferred embodiment of devices fabricated on a silicon on sapphire substrate having a single layer silicon oxide bonding interface.

FIG. 2 is a perspective view of the second preferred embodiment of devices fabricated on a silicon on sapphire substrate having a dual layer silicon oxide bonding interface.

FIG. 3 is a process flow diagram of teaching how to fabricate the silicon on sapphire substrate and the device of the first and second preferred embodiments.

FIG. 4A to FIG. 4C are partially processed silicon wafer of the third preferred embodiment ready for bonding.

FIG. 5A to 5B, are partially processed sapphire wafer of the third preferred embodiment ready before bonding.

FIG. 6A is a diagram of the third preferred embodiment showing that how to bond the prefabricated silicon wafer to the prefabricated sapphire wafer.

FIG. 6B is a diagram of the third preferred embodiment showing that a thinning process done by a Chemical-Mechanical Polish (CMP) step after silicon and sapphire wafers are joined.

### DETAILED DESCRIPTION OF THE INVENTION

The present invention is a method of making devices with passive components built on silicon on sapphire. The devices made have a silicon layer that is defect free in contrast to the prior art processes, and the sapphire substrate is totally transparent to RF radiation and optical light. Although the sapphire is our choice at this point as the substrate material, many other types of insulator substrates can also substitute for the sapphire substrate used here as well, for example, any organic material (e.g., polyimide and plastic) and silicate glass. This method fabricates high quality silicon on sapphire substrate for RF (radio frequency) and other types of applications. A low-cost method proposed here will produce good quality silicon on sapphire substrate with low defect density.

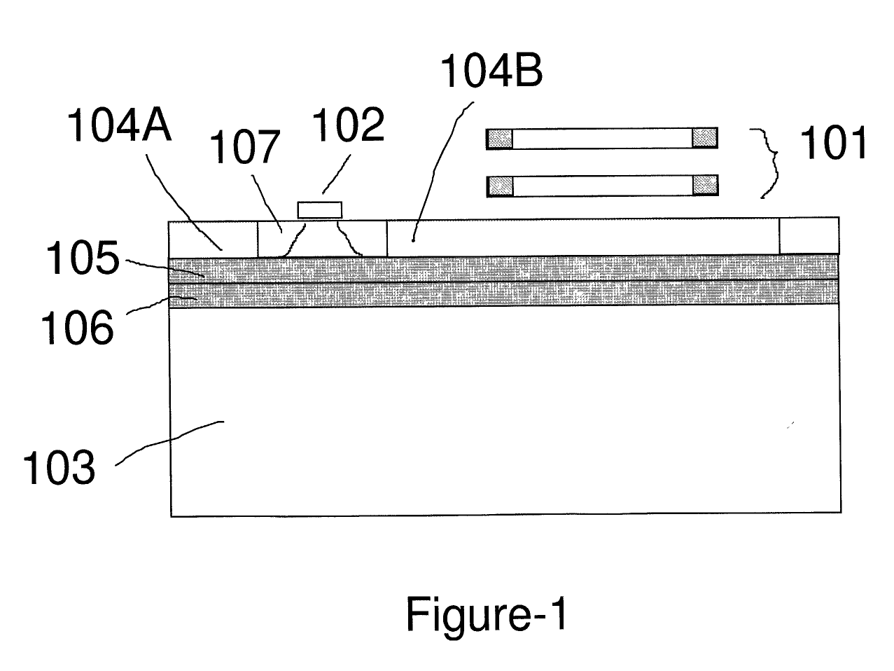

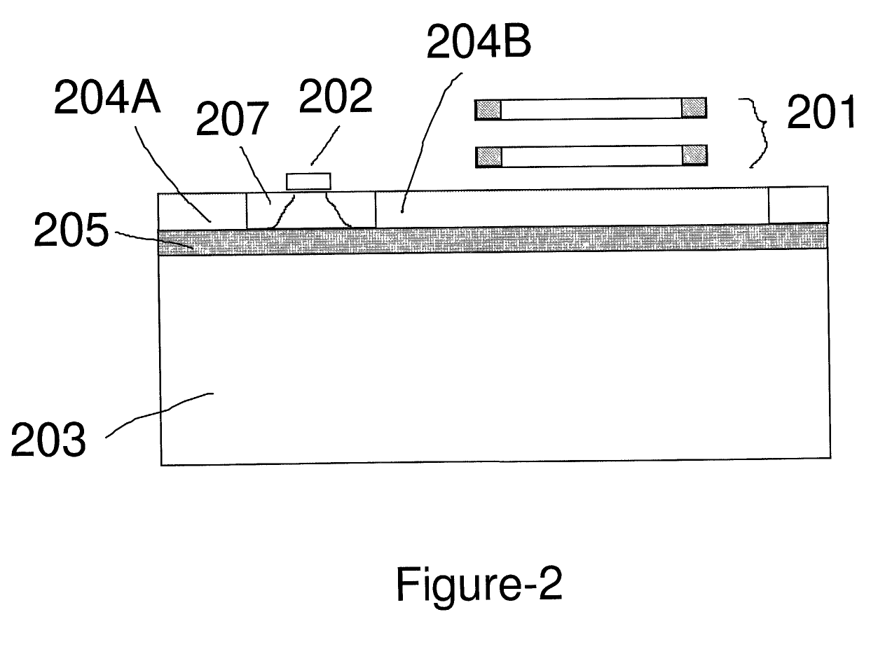

Various embodiments of the device structure are shown in FIGS. 1 and 2. These figures and structures are also described and claimed in U.S. patent application No. YYY, entitled SILICON ON SAPPHIRE STRUCTURE (DEVICES) WITH BUFFER LAYER, to the same inventors, which is herein incorporated by reference in its entirety.

The CMOS FET devices (102) are fabricated in the silicon layer (107) on the sapphire substrate (103). Devices are isolated by a known shallow trench isolation (STI) process, resulting in layer 104A and 104B. A representative passive component (e.g. inductive coil ) is shown as 101. There two oxide layers that serve as the buffer layers (105, 106) between the substrate 103 and the silicon device layer 107. The silicon dioxide layer 105 is thermally grown on the silicon wafer to preserve good interface property and device characteristics. The other oxide layer 106 is deposited on the sapphire substrate which can be silicon dioxide film deposited by a CVD tool or other types of dielectric film with good adhesive properties.

The passive components 101, (capacitors, inductors, resistors, etc.) can be fabricated together with the device interconnect process Since there is no underlying silicon substrate, there is no Eddy current type of loss of RF signal.

Another similar embodiment of silicon on sapphire structure is shown in FIG. 2. Here, only one oxide bonding layer 205 is shown. The oxide layer is formed on the silicon wafer prior to wafer bonding. The CMOS FET devices (202) is fabricated in the silicon layer (207) on the sapphire substrate (203). Devices are isolated by shallow trench isolation (STI) process, is shown as layer 204A and 204B. A representee passive component (e.g. inductive coil) is shown as 201.

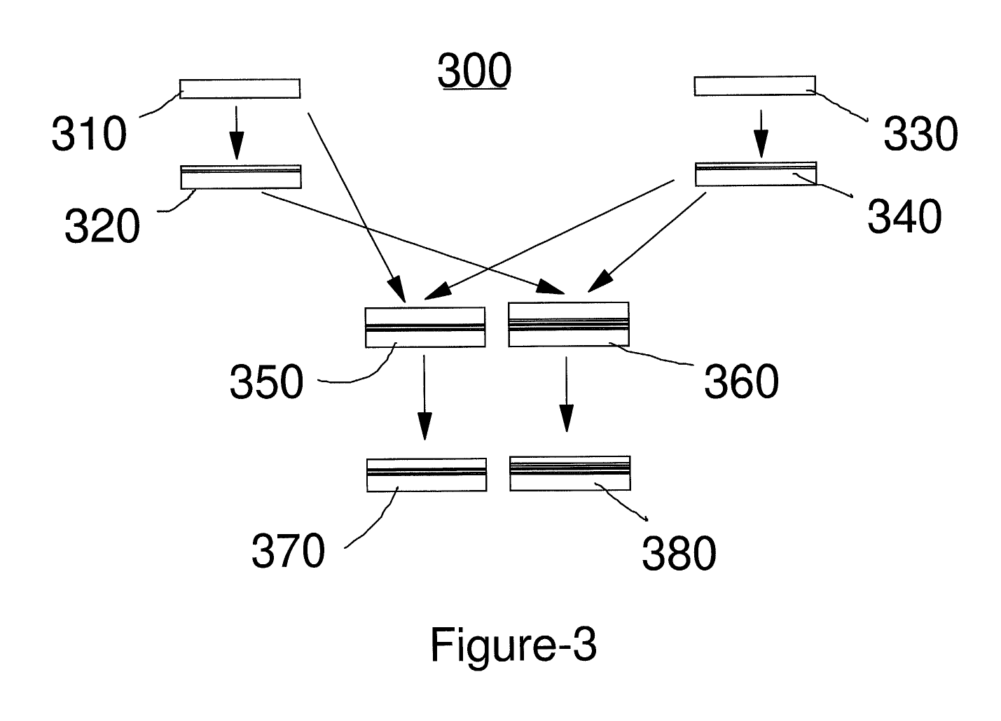

FIG. 3 is a process flow showing fabrication steps of the first and second preferred embodiments to form silicon on sapphire substrate. The process 300 begins with a sapphire substrate 310 and a silicon substrate 330. An oxide layer is formed on the silicon substrate 340. After surface cleaning, the silicon substrate with an oxide bonding layer 340 is thermally joined with the sapphire substrate 310. The resulting structure is shown as substrate 350 having a single oxide bonding layer. After a thinning process is carried out on the silicon wafer layer, the final silicon on sapphire substrate is shown in 370.

A preferred embodiment is to have a dual oxide bonding layer. The first bonding oxide layer is formed on the silicon substrate 340, and the second bonding oxide layer is formed on the sapphire substrate 320. Two substrates are bonded at two oxide surfaces to form the third substrate 360 so that thermal mismatching at bonding interface is eliminated. After a thinning process is carried out on the silicon wafer layer, the final silicon on sapphire substrate is shown in 380.

A third embodiment of the invention is to prefabricate bonding structure on both silicon and sapphire substrates prior to wafer bonding. These prefabricated bonding structure will enhance the quality of the bonding process and resulting in an improved silicon on sapphire substrate. For example, these prefabricated structures can be used as a polish stop indicator to precisely control the final silicon layer thickness after the thinning process. The prefabricated structure can also allow better thermal dissipation on the bonded substrate. This is because some portions of the interface oxide is thinner than the rest portion.

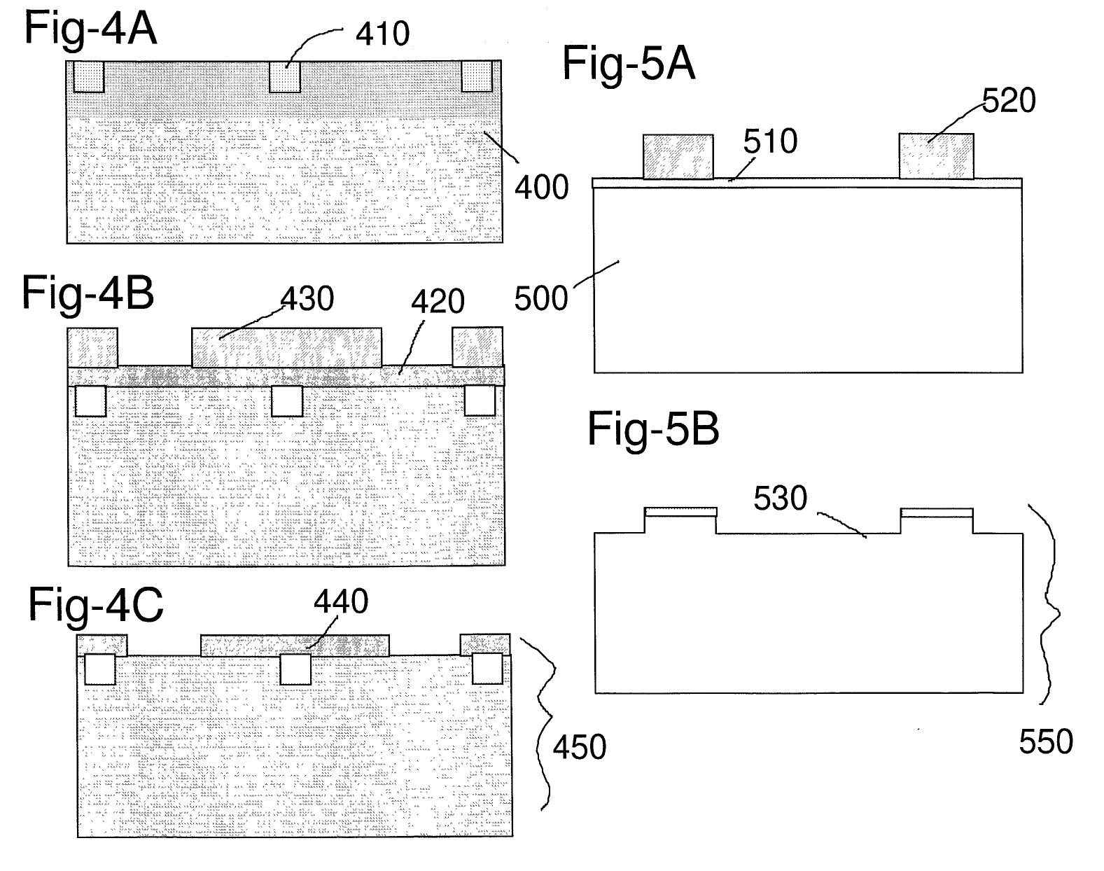

The detailed processing steps are described in FIGS. 4 to 6.

A polish stop features 410 as shown in FIG. 4A are prefabricated on a silicon substrate 400. This is done by first patterning and etching shallow trenches on the silicon wafer 400. These trenches are filled with oxide and planarized to the surface. A layer of silicon dioxide 420 is formed on the wafer 400. This layer can be formed by thermal oxidation and/or by a CVD oxide deposition to have good oxide to silicon interface properties. The thickness of this layer can be in the range of 10-200 nm. A photoresist pattern 430 is formed on top of the oxide layer by using a conventional lithographic process step as shown in FIG. 4B. A RIE, or reactive ion etch process is used to etch the oxide layer 430. As the result, a patterned oxide structure 440 is formed on the silicon substrate 400 prior to wafer bonding. An oxide (or other dielectric) layer 510 is deposited on the sapphire wafer 500 as shown in the FIG. 5A. This layer is used to be flexible enough to eliminate the stress-induced effects between the device silicon layer and the underlying sapphire substrate during the processing of the substrate as well as the processing of device.

Both silicon and sapphire are materials with high melting points. The stress can be very high during the high temperature annealing of bonding silicon directly on a sapphire substarte. This is the reason why the existing processes of bonding silicon on sapphire resulted on high defect density. On the other hand, silicon oxide has a relative lower melting point. It becomes partially viscous at around 700 C. and fully viscous at 1100 C. By inserting a silicon oxide layer in between silicon and sapphire wafers as a buffer can significantly reduce the stress induced defects.

The good thermal conductivity benefits the post bonding annealing process because uniform temperature across the wafer substrate is more uniform. Compared to silicon bonded to silicon process, the sapphire is still less thermally conductive to silicon substrate. The thickness can be varied by the processing steps is typically in the range from 10-50 nm to several microns. A typical method to deposit this layer is through a LPCVD or PECVD process. A photoresist pattern 520 is formed on the sapphire substrate 500. Noted that resist pattern 520 and resist pattern 430 are mirror-image to each other. Therefore, same mask can be used to pattern both substrates, for example a positive resist is used to form an image pattern on one substrate and negative resist to form the corresponding mirror pattern the other.

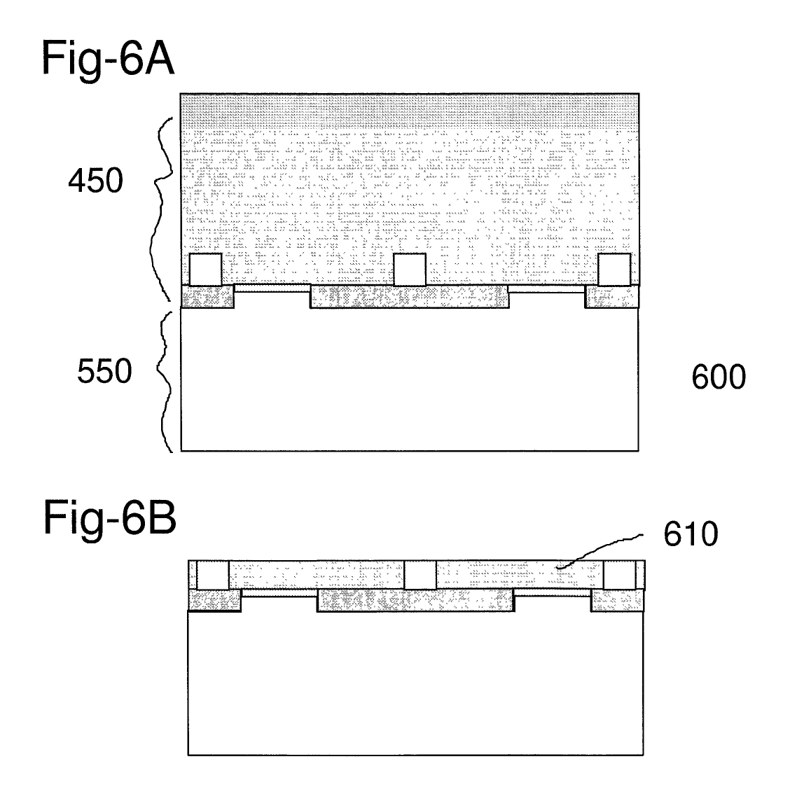

A reactive ion etching is carried out to etch oxide layer 5 10 and the sapphire substrate. The total etch depth 530, oxide plus sapphire must be equal or smaller than the oxide thickness of 420. However, slight thickness deviation is tolerable. At high bonding temperature, the oxide layer becomes “flowable”, when silicon substrate 450 and sapphire substrate 550 are joined at high temperature (greater than 1000C.) and under certain pressure as shown in FIG. 6A, the bonding oxide layers will flow locally forming the structure 600.

In one preferred embodiment, the silicon layer is thinned to the surface of polish stop level, or the shallow trench 410 surface. Thinning can done using a conventional chemical-machnical polishing process. The final structure of silicon on sapphire substrate is shown in FIG. 6B. The silicon thickness 610 is in the range of 10-1000 nm. The structure has a thin oxide bonding region and a thick oxide bonding region. The heat generated in the silicon layer during peak device operation period can be easily dissipated away through the thin oxide layer into sapphire substrate.

The polish stop is some patterned feature on the substrate using material different from the substrate material. So, in the CMP process the etch rate can be changed due to the dispearing of the material on the stop. Thus,can be detected with some machine motion sensors.

The sapphire substrate is optically transparent, therefore the prefabricated bonding patterns on both substrates can be easily aligned during wafer bonding without using any expensive alignment tool. For example, features that formed on the silicon substarte can be optically “seen” through the sapphire substarte. Therefore, a conventional microscope can be used to insure a perfect alignment during bonding. In other words, the features on the silicon wafer can be aligned precisely to the features on the sapphire wafer.

The bonding of pattern the wafers is difficult because when the two wafers are bonded face to face. Conventional optical alignment can not be done due to the opque silicon (or other) substrate. Normally infarad light is used to see through the pattern on the wafer surface since it can pass through the silicon. But, the image is very fuzzy due to its long wavelength and interfered by the nearby heat source (light bulb etc.) Using the transparent sapphire as the substrate, that the optical light can easily pass through, the alignment can be easy and accurate.Sapphire is also an excellent thermally conductive material, therefore, during wafer bonding uniform temperature distribution on the sapphire substrate will surely enhance the bonding properties and material quality.

We claim:

1. A method of manufacturing a silicon on sapphire structure comprising the steps of:
forming a first silicon oxide layer on a silicon substrate;
forming a second silicon oxide layer on a sapphire substrate;
bonding the silicon substrate to the sapphire substrate by joining the first silicon oxide layer to the second oxide layer.

2. A method, as in claim 1, where the first silicon oxide layer is formed on the silicon layer by thermally growing the silicon oxide layer on the silicon substrate.

3. A method, as in claim 1, where the first silicon oxide layer is formed to the silicon layer by chemical vapor depositing the silicon oxide layer on the silicon substrate.

4. A method, as in claim 1, where the second silicon oxide layer is formed to the sapphire layer by depositing the silicon oxide layer on the sapphire layer.

5. A structure, as in claim 1, where the silicon layer comprises a plurality of silicon islands which are isolated by a plurality of isolation regions.

6. A method of manufacturing a silicon on sapphire structure comprising the steps of:
forming a silicon oxide layer to a silicon substrate; and
wafer bonding the silicon substrate to a sapphire substrate using silicon oxide as the interface material.

7. A method, as in claim 6, where the silicon oxide layer is formed on the silicon substrate by thermally growing the silicon oxide layer on the silicon substrate.

8. A method, as in claim 6, where the silicon oxide layer is formed to the silicon layer by chemical vapor depositing the silicon oxide layer on the silicon substrate.

9. A structure, as in claim 6, where the silicon layer comprises a plurality of silicon islands which are isolated by a plurality of isolation regions.

10. A method of manufacturing a silicon on sapphire structure comprising the steps of:
forming a first patterned silicon oxide layer to a silicon substrate;
forming a second patterned silicon oxide layer on a sapphire substrate; and
bonding the silcon substrate to the sapphire substrate by joining the first patterned silicon oxide layer to the second patterned oxide layer.

11. A method, as in claim 10, the first patterned oxide layer has a positive pattern image which is substantially matched to the negative pattern image of the second patterned oxide layer.

12. A method, as in claim 10, where the thickness of the first patterned oxide layer is equivalent to the thickness of the second oxide layer and the etched depth of sapphire substrate, so that after the bonding step, the first patterned oxide layer and the second patterned oxide are sandwiched in between silicon substrate and sapphire substrate.

13. A method, as in claim 10, wherehe thickness of the first patterned oxide layer is thicker than that of the second patterned oxide layer.

14. A method, as in claim 10, further comprising the step of the aligning the first patterned oxide layer and the second patterned oxide layer with an optical tool that is able to transmit light through the sapphire substrate.

15. A method, as in claim 10, further comprising the step of thinning down the silicon layer ito a final thickness in the range from 10 nm to 1000 nm.

16. A method, as in claim 10, further comprising the steps of:
installing a polish stop feature on the first patterned oxide; and
thinning down the silicon layer after the boding to the surface of the polish stop feature.
